(19) United States
(12) Patent Application Publication
(10) Pub. No.: US 2023/0402352 A1
(43) Pub. Date: Dec. 14, 2023

(54) LEAD FRAME AND ELECTRONIC COMPONENT

(71) Applicant: TDK CORPORATION, Tokyo (JP)

(72) Inventors: Kazuma YAMAWAKI, Tokyo (JP); Hiraku HIRABAYASHI, Tokyo (JP)

(73) Assignee: TDK CORPORATION, Tokyo (JP)

(21) Appl. No.: 18/318,893

(22) Filed: May 17, 2023

(30) Foreign Application Priority Data
Jun. 8, 2022 (JP) 2022-092992

(51) Int. Cl. H01L 23/495; H01L 23/00

(52) U.S. Cl. CPC H01L 23/49565; H01L 24/48; H01L 24/49; H01L 23/4952; H01L 2224/48245; H01L 2224/49171; H01L 2224/48257

(57) ABSTRACT

A lead frame includes a die pad, a plurality of leads, and a frame member. The frame member includes a first connection bar extending in a first direction and a second connection bar extending in a second direction. The die pad is connected to the second connection bar. The plurality of leads include a plurality of first leads connected to the first connection bar and a plurality of second leads connected to the second connection bar. The number of the plurality of second leads is smaller than the number of the plurality of first leads. Each of the plurality of second leads is connected to one corresponding first lead of the plurality of first leads.

### CROSS REFERENCE TO RELATED APPLICATIONS

This application claims the benefit of Japanese Priority Patent Application No. 2022-092992 filed on Jun. 8, 2022, the entire contents of which are incorporated herein by reference.

### BACKGROUND

The technology relates to a lead frame for an electronic component and an electronic component manufactured using the lead frame.

Packages such as Dual Flatpack No-leaded (DFN) packages that are provided with no lead terminals extending outward from a package body are known as packages for electronic components, such as semiconductor devices, suitable for miniaturization. In such a DFN package, a plurality of terminals are provided on a surface of a package body. The plurality of terminals are bonded to a conductive layer on a board by soldering, for example.

In general, a lead frame, which includes a die pad on which a chip is mounted and a plurality of leads, is used to manufacture the DFN package. The plurality of terminals are formed by plating parts of surfaces of the plurality of leads. In order to form good fillets when mounting an electronic component on the board, it is desirable to plate the entire surfaces of the leads that are exposed from the surface of the package body.

US 2015/0255378 A1 and JP 2016-167532 A disclose a technology for plating entire surfaces of leads exposed from a surface of a package body. US 2015/0255378 A1 describes a lead frame in which inner leads are connected to outer leads connected to a lead frame rim. The inner leads are connected to the lead frame rim through inner suspension leads.

In US 2015/0255378 A1, the outer leads are cut from the lead frame rim after a semiconductor chip is encapsulated by an encapsulating resin. After the outer leads are cut, the lead frame rim and the outer leads still maintain an electrical connection relationship. In US 2015/0255378 A1, plating is applied in this state to form a plated film on entire surfaces of the outer leads exposed from the encapsulating resin.

JP 2016-167532 A describes a lead frame similar to the lead frame described in US 2015/0255378 A1. A first connection bar and a second connection bar of JP 2016-167532 A correspond to the lead frame rim of US 2015/0255378 A1. In JP 2016-167532 A, extensions are connected to leads connected to the first connection bar. The extensions are connected to the second connection bar.

In the lead frames described in US 2015/0255378 A1 and JP 2016-167532 A, leads to be used as terminals and leads not to be used as terminals are coupled to each other. If an electronic component is manufactured using such a lead frame, the leads not to be used as terminals are also exposed from the package body. This increases the number of leads exposed from the package body and increases the risk of moisture intrusion into the package body through the interfaces between the leads and the encapsulating resin.

### SUMMARY

A lead frame according to one embodiment of the technology is a lead frame for an electronic component. The lead frame includes a die pad, a plurality of leads, and a frame member surrounding the die pad and the plurality of leads. The frame member includes a first connection bar extending in a first direction and a second connection bar extending in a second direction. The die pad is connected to the second connection bar. The plurality of leads include a plurality of first leads connected to the first connection bar and a plurality of second leads connected to the second connection bar. The number of the plurality of second leads is smaller than the number of the plurality of first leads. Each of the plurality of second leads is connected to one corresponding first lead of the plurality of first leads.

An electronic component according to one embodiment of the technology is an electronic component manufactured using the lead frame according to one embodiment of the technology. The electronic component includes a chip mounted on the die pad and an encapsulating resin encapsulating the chip.

In the lead frame and the electronic component according to one embodiment of the technology, the plurality of leads include a plurality of first leads connected to the first connection bar of the frame member and a plurality of second leads connected to the second connection bar of the frame member. The number of the plurality of second leads is smaller than the number of the plurality of first leads. Thus, according to one embodiment of the technology, the risk of moisture intrusion into the package body can be reduced.

Other and further objects, features, and advantages of the technology will become apparent more fully from the following description.

### BRIEF DESCRIPTION OF THE DRAWINGS

The accompanying drawings are included to provide a further understanding of the disclosure and are incorporated in and constitute a part of this specification. The drawings show example embodiments and, together with the specification, serve to explain the principles of the technology.

FIG. 1 is a perspective view of an electronic component according to a first example embodiment of the technology.

FIG. 2 is a perspective view of the electronic component according to the first example embodiment of the technology.

FIG. 3 is an enlarged perspective view of a part of the electronic component shown in FIG. 2.

FIG. 4 is a plan view of a lead frame structure in the first example embodiment of the technology.

FIG. 5 is a plan view of a lead frame according to the first example embodiment of the technology.

FIG. 6 is a plan view of a connection relationship between a plurality of first leads and a plurality of electrode pads in the electronic component according to the first example embodiment of the technology.

FIG. 7 is a plan view of a connection relationship between a plurality of first leads and a plurality of electrode pads in a modification example of the electronic component according to the first example embodiment of the technology.

FIG. 8 is a plan view of a connection relationship between a plurality of first leads and a plurality of electrode pads in an electronic component according to a second example embodiment of the technology.

### DETAILED DESCRIPTION

An object of the technology is to provide a lead frame that can reduce the risk of moisture intrusion into a package body, and an electronic component using the lead frame.

In the following, some example embodiments and modification examples of the technology are described in detail with reference to the accompanying drawings. Note that the following description is directed to illustrative examples of the disclosure and not to be construed as limiting the technology. Elements including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Similar elements are denoted with the same reference numerals to avoid redundant descriptions. Note that the description is given in the following order.

### First Example Embodiment

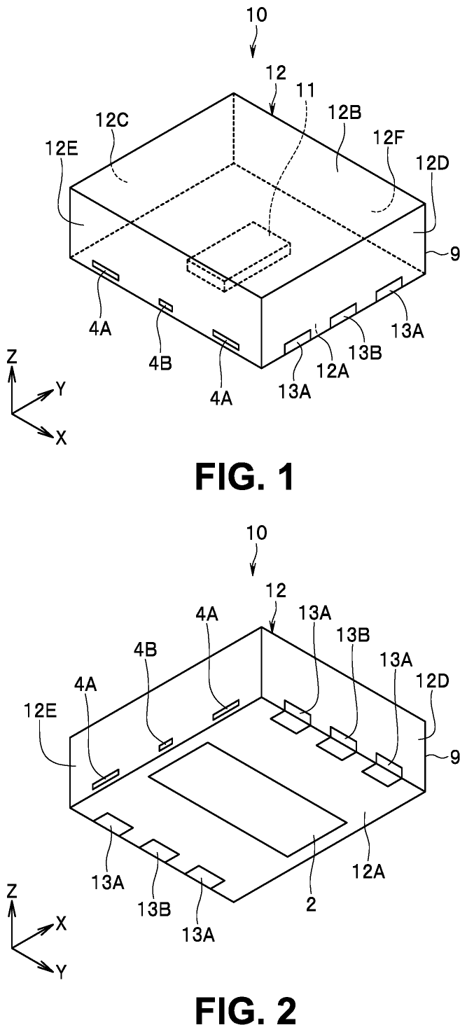

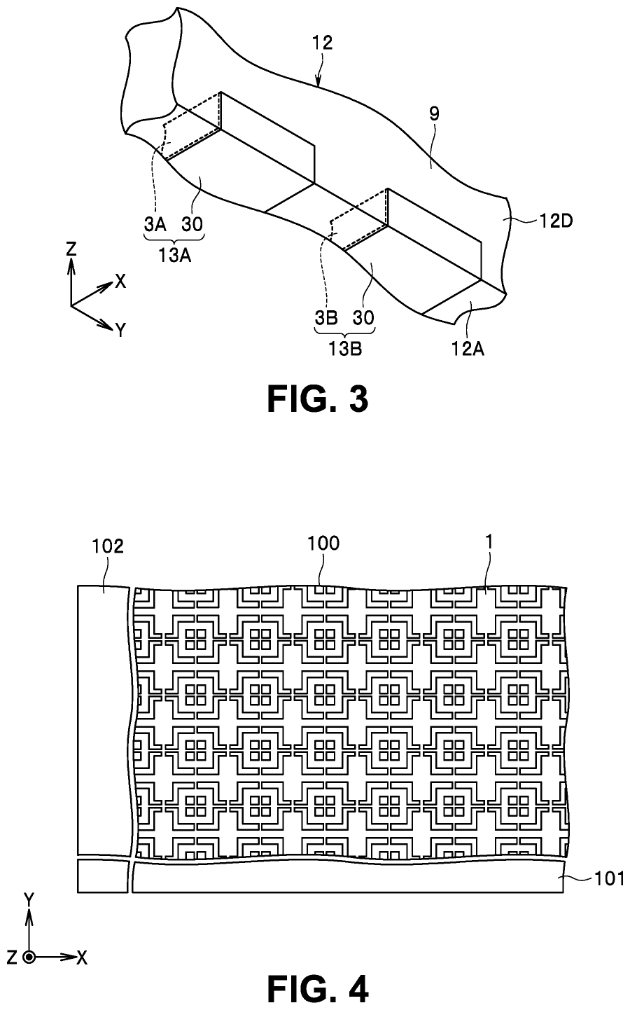

First, with reference to FIGS. 1 to 3, an electronic component according to a first example embodiment of the technology will be described. FIGS. 1 and 2 are perspective views of the electronic component. FIG. 3 is an enlarged perspective view of a part of the electronic component shown in FIG. 2.

An electronic component 10 according to the example embodiment is an electronic component manufactured using a lead frame according to the example embodiment. The electronic component 10 includes a chip 11, an encapsulating resin 9, and a plurality of terminals. The chip 11 is mounted on a die pad 2 of the lead frame. The chip 11 includes a plurality of electrode pads. The plurality of electrode pads are electrically connected to a plurality of respective terminals. The plurality of terminals are constituted of part of the lead frame. The encapsulating resin 9 encapsulates the chip 11. The encapsulating resin 9 constitutes a large portion of a package body (hereinafter simply referred to as a body) 12 of the electronic component 10.

The plurality of terminals include a plurality of first terminals and at least one second terminal. In the examples shown in FIGS. 1 to 3, each first terminal is indicated by the reference sign 13A, and each second terminal is indicated by the reference sign 13B. In the examples, the plurality of terminals include a plurality of second terminals 13B as the at least one second terminal.

In particular, in the example embodiment, the body 12 is approximately in the shape of a rectangular parallelepiped. The body 12 has a bottom surface 12A, a top surface 12B, and four side surfaces 12C to 12F, which constitute an outer periphery of the body 12. The bottom surface 12A and the top surface 12B are opposite to each other. The side surfaces 12C and 12D are opposite to each other. The side surfaces 12E and 12F are opposite to each other. The side surfaces 12C to 12F are perpendicular to the bottom surface 12A and the top surface 12B. FIG. 1 shows the electronic component 10 viewed from the side of the top surface 12B. FIG. 2 shows the electronic component 10 viewed from the side of the bottom surface 12A.

Here, X, Y, and Z directions are defined as shown in FIGS. 1 to 3. The X, Y, and Z directions are orthogonal to one another. In the example embodiment, the Z direction refers to a direction that is perpendicular to the bottom surface 12A and that is toward the top surface 12B from the bottom surface 12A. The opposite directions to the X, Y, and Z directions are defined as −X, −Y, and −Z directions, respectively.

A direction parallel to the Y direction corresponds to a “first direction” in the technology, and a direction parallel to the X direction corresponds to a “second direction” in the technology. In an example embodiment, the first direction and the second direction are orthogonal to each other. Note that the first direction and the second direction may intersect with each other at an angle other than 90 degrees.

As shown in FIGS. 1 and 2, the bottom surface 12A is located at an end of the body 12 in the −Z direction. The top surface 12B is located at an end of the body 12 in the Z direction. The side surface 12C is located at an end of the body 12 in the −X direction. The side surface 12D is located at an end of the body 12 in the X direction. The side surface 12E is located at an end of the body 12 in the −Y direction. The side surface 12F is located at an end of the body 12 in the Y direction.

Some of the plurality of first terminals 13A and the plurality of second terminals 13B are arranged on and near a first ridge line between the bottom surface 12A and the side surface 12C. In the example shown in FIGS. 1 and 2, two first terminals 13A aligned in the Y direction are arranged on and near the first ridge line. One second terminal 13B is arranged between the two first terminals 13A on and near the first ridge line.

Similarly, some others of the plurality of first terminals 13A and the plurality of second terminals 13B are arranged on and near a second ridge line between the bottom surface 12A and the side surface 12D. In the example shown in FIGS. 1 and 2, two other first terminals 13A aligned in the Y direction are arranged on and near the second ridge line. One other second terminal 13B is arranged between the two other first terminals 13A on and near the second ridge line.

As described above, the plurality of terminals (plurality of first terminals 13A and plurality of second terminals 13B) are constituted of part of the lead frame. The electronic component 10 further includes a plurality of plating layers 30 constituting other portions of the plurality of terminals. A major portion of each of the plurality of terminals is present in the body 12. Each of the plurality of plating layers 30 constitutes a portion of a corresponding terminal of the plurality of terminals, the portion being exposed from the body 12.

The die pad 2 has an exposed surface that is not covered with the encapsulating resin 9. The exposed surface of the die pad 2 is arranged in the bottom surface 12A. The electronic component 10 further includes a not-shown plating layer, which covers a portion of the exposed surface of the die pad 2, the portion being located in the bottom surface 12A.

In FIGS. 1 and 2, the reference sign 4A indicates a second lead, and the reference sign 4B indicates a connecting lead. In FIG. 3, the reference signs 3A and 3B indicate first leads. The first leads 3A and 3B, the second leads 4A, and the connecting leads 4B will be described later in detail.

The electronic component 10 is mounted on a mounting board with the bottom surface 12A of the body 12 facing the mounting board. The electronic component 10 shown in FIGS. 1 to 3 is a Dual Flatpack No-leaded (DFN) package having no lead terminals extending outward from the body 12.

At least one of the plurality of second terminals 13B may be electrically connected to the ground in a state where the electronic component 10 is mounted on the mounting board.

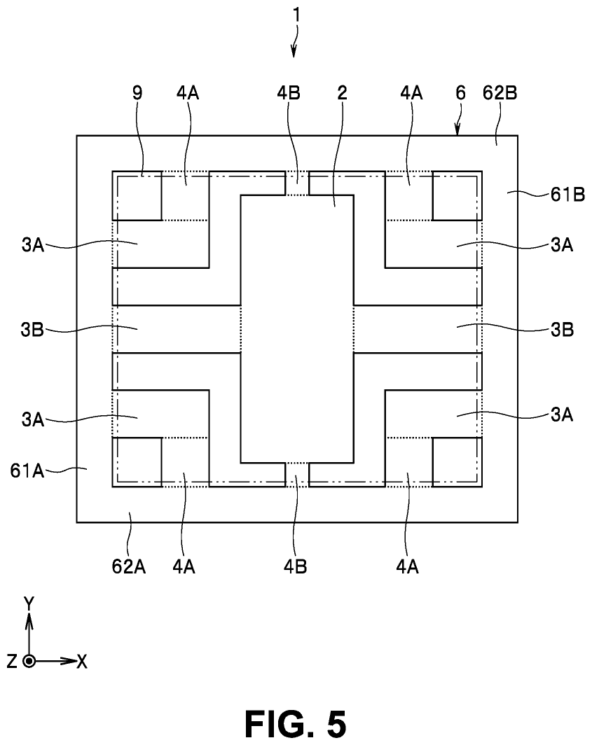

Next, the lead frame according to the example embodiment will be described with reference to FIGS. 4 and 5. FIG. 4 is a plan view of the lead frame structure in the example embodiment. FIG. 5 is a plan view of the lead frame according to the example embodiment. Note that, in FIGS. 4 and 5, the X, Y, and Z directions are shown as in FIGS. 1 to 3. In FIGS. 4 and 5, the X, Y and Z directions are defined such that the relationship between the orientation of die pad 2 and the X, Y, and Z directions is the same as that in FIGS. 1 to 3.

A lead frame structure 100 shown in FIG. 4 includes a plurality of lead frames 1 for the electronic components 10. In the example shown in FIG. 4, the plurality of lead frames 1 are arranged in such a matrix of a plurality of the lead frames 1 in the X direction by a plurality of the lead frames 1 in the Y direction. The lead frame structure 100 is made by processing a metal plate made of an alloy containing Cu or Fe, for example.

The structure of the lead frames 1 will be described below, focusing on one lead frame 1. FIG. 5 shows the one lead frame 1. The lead frame 1 includes the die pad 2, the plurality of leads, and a frame member 6 surrounding the die pad 2 and the plurality of leads.

The frame member 6 includes two first connection bars 61A and 61B each extending in a direction parallel to the Y direction, and two second connection bars 62A and 62B each extending in a direction parallel to the X direction. One end of the first connection bar 61A is connected to one end of the second connection bar 62A. The other end of the second connection bar 62A is connected to one end of the first connection bar 61B. The other end of the first connection bar 61B is connected to one end of the second connection bar 62B. The other end of the second connection bar 62B is connected to the other end of the first connection bar 61A.

The plurality of leads include a plurality of first leads each connected to the first connection bar 61A or 61B and a plurality of second leads 4A each connected to the second connection bar 62A or 62B. Some of the plurality of first leads are connected to the die pad 2. In the following, the first leads connected to the die pad 2 are each denoted by the reference sign 3B, and the first leads not connected to the die pad 2 are each denoted by the reference sign 3A. The plurality of leads include a plurality of first leads 3A and at least one first lead 3B as the plurality of first leads. The at least one first lead 3B corresponds to an “at least one particular first lead” in the technology. In particular, in the example embodiment, the at least one first lead 3B is a plurality of first leads 3B.

The number of the plurality of second leads 4A is smaller than the number of the plurality of first leads, i.e., the total number of the plurality of first leads 3A and the plurality of first leads 3B. In the example shown in FIG. 5, the number of the first leads 3A is four, the number of the first leads 3B is two, and the number of the second leads 4A is four. Each of the plurality of second leads 4A is connected to one corresponding first lead of the plurality of first leads, more specifically, one corresponding first lead 3A of the plurality of first leads 3A not connected to the die pad 2.

In FIG. 5, two first leads 3A and one first lead 3B are arranged between the die pad 2 and the first connection bar 61A (on the left side of the die pad 2 in FIG. 5). The two first leads 3A are aligned along the first connection bar 61A. The one first lead 3B is arranged between the two first leads 3A. Each of the two first leads 3A and the one first lead 3B is connected to the first connection bar 61A and extends in the X direction from the first connection bar 61A. Each of the two second leads 4A of the plurality of second leads 4A is connected near an end portion of one corresponding first lead 3A of the two first leads 3A, the end portion being opposite to the first connection bar 61A. The end portion, which is opposite to the first connection bar 61A, of the one first lead 3B is connected to the die pad 2.

In FIG. 5, two other first leads 3A and one other first lead 3B are arranged between the die pad 2 and the first connection bar 61B (on the right side of the die pad 2 in FIG. 5). The two other first leads 3A are aligned along the first connection bar 61B. The one other first lead 3B is arranged between the two other first leads 3A. Each of the two other first leads 3A and the one other first lead 3B is connected to the first connection bar 61B and extends in the −X direction from the first connection bar 61B. Each of the two other second leads 4A of the plurality of second leads 4A is connected near an end portion of one corresponding first lead 3A of the two other first leads 3A, the end portion being opposite to the first connection bar 61B. The end portion, which is opposite to the first connection bar 61B, of the one other first lead 3B is connected to the die pad 2.

In FIG. 5, the boundary between each of the first leads 3A and 3B and the first connection bar 61A or 61B, the boundary between each of the first leads 3A and each of the second leads 4A, and the boundary between each of the first leads 3B and the die pad 2 are indicated by dotted lines.

The plurality of leads further include a plurality of connecting leads 4B. In the example shown in FIG. 5, the number of the connecting leads 4B is two. One of the two connecting leads 4B is connected to the die pad 2 and the second connection bar 62A, while the other is connected to the die pad 2 and the second connection bar 62B. Hence, the die pad 2 is indirectly and electrically connected to the second connection bars 62A and 62B via the connecting leads 4B. Note that the number of the connecting leads 4B is not limited to two and may be three or more. FIG. 5 shows an example that the dimension of the connecting leads 4B in the X direction is smaller than the dimension of the second leads 4A in the X direction. However, the dimension of the connecting leads 4B in the X direction may be equal to the dimension of the second leads 4A in the X direction or may be larger than the dimension of the second leads 4A in the X direction.

In FIG. 5, two second leads 4A and one connecting lead 4B are arranged between the die pad 2 and the second connection bar 62A (on the lower side of the die pad 2 in FIG. 5). The two second leads 4A are aligned along the second connection bar 62A and also connected to the second connection bar 62A. The one connecting lead 4B is arranged between the two second leads 4A. In FIG. 5, two other second leads 4A and one other connecting lead 4B are arranged between the die pad 2 and the second connection bar 62B (on the upper side of the die pad 2 in FIG. 5). The two other second leads 4A are aligned along the second connection bar 62B and also connected to the second connection bar 62B. The one other connecting lead 4B is arranged between the two other second leads 4A. In FIG. 5, the boundary between the die pad 2 and each of the connecting leads 4B, the boundary between each of the second leads 4A and the second connection bar 62A or 62B, and the boundary between the each of the connecting leads 4B and the second connection bar 62A or 62B are indicated by dotted lines.

In FIG. 5, an area enclosed by a dashed double-dotted rectangle with the reference numeral 9 indicates an area encapsulated by the encapsulating resin 9 in the electronic component 10 manufactured using the lead frame 1. An area outside the dashed double-dotted rectangle with the reference numeral 9 is an area that is to be removed in a manufacturing process of the electronic component 10. The first connection bars 61A and 61B and the second connection bars 62A and 62B are located in the area to be removed in the manufacturing process of electronic component 10. In the manufacturing process of the electronic component 10, a portion of each of the first leads 3A and 3B is also removed, the portion being in the vicinity of the boundary with the first connection bar 61A or 61B.

In the manufacturing process of the electronic component 10, a portion of each of the plurality of second leads 4A and the plurality of connecting leads 4B is also removed, the portion being in the vicinity of the boundary with the second connection bar 62A or 62B. As a result, as shown in FIGS. 1 and 2, an end surface of each of the plurality of second leads 4A and the plurality of connecting leads 4B is exposed at a corresponding one of the side surfaces 12E and 12F of the body 12 of the electronic component 10.

So far, focus has been placed on the describing of the single lead frame 1. As described above, the lead frame structure 100 in the example embodiment includes the plurality of lead frames 1. The lead frame structure 100 also includes a plurality of first connection bars 61A, a plurality of first connection bars 61B, a plurality of second connection bars 62A, and a plurality of second connection bars 62B.

The plurality of first connection bars 61A and the plurality of first connection bars 61B are arranged in the X direction such that the first connection bars 61A and the first connection bars 61B are alternately disposed. Each of the first connection bars 61A and 61B has, in a direction parallel to the Y direction, a dimension corresponding to the plurality of lead frames 1 aligned in the Y direction.

The plurality of second connection bars 62A and the plurality of second connection bars 62B are arranged in the Y direction such that the second connection bars 62A and the second connection bars 62B are alternately disposed and cross the plurality of first connection bars 61A and 61B. Each of the second connection bars 62A and 62B has, in a direction parallel to the X direction, a dimension corresponding to the plurality of lead frames 1 aligned in the X direction.

The lead frame structure 100 includes a third connection bar 101 located at an end of the lead frame structure 100 in the −Y direction, a not-shown fourth connection bar located at an end of the lead frame structure 100 in the Y direction, a fifth connection bar 102 located at an end of the lead frame structure 100 in the −X direction, and a not-shown sixth connection bar located at an end of the lead frame structure 100 in the X direction. The plurality of first connection bars 61A and the plurality of first connection bars 61B are each connected to the third connection bar 101 and the fourth connection bar. The plurality of second connection bars 62A and the plurality of second connection bars 62B are each connected to the fifth connection bar 102 and the sixth connection bar.

Next, a manufacturing method of the electronic component 10 will be described. In the manufacturing method of the electronic component 10, first, the chip 11 including a plurality of electrode pads is mounted on the die pad 2 of the lead frame 1. The chip 11 has a first surface on which the plurality of electrode pads are arranged and a second surface opposite to the first surface. The chip 11 is mounted on the die pad 2 so that the second surface faces the die pad 2. Next, the plurality of electrode pads of the chip 11 and the first leads 3A and 3B of the lead frame 1 are electrically connected by wire bonding using a plurality of wires 7.

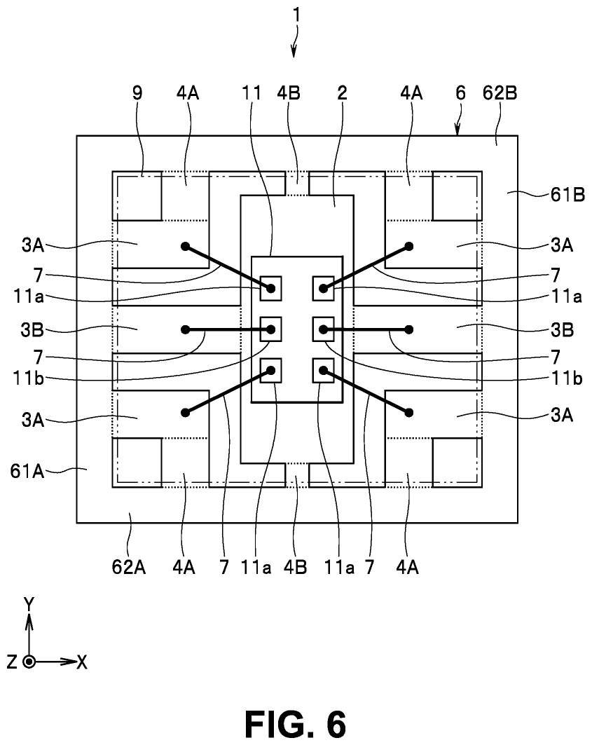

Here, with reference to FIG. 6, a connection relationship between the first leads 3A and 3B and the plurality of electrode pads will be described. In FIG. 6, the electrode pads connected to the first leads 3A are denoted by the reference sign 11a, while the electrode pads connected to the first leads 3B are denoted by the reference sign 11b. The chip 11 may include a plurality of electrode pads 11a and at least one electrode pad 11b as the plurality of electrode pads. In the example shown in FIG. 6, the number of the electrode pads 11a is four, and the number of the electrode pads 11b is two.

The at least one electrode pad 11b corresponds to an “at least one particular electrode pad” in the technology. The at least one electrode pad 11b may be a ground pad electrically connected to the ground. Alternatively, the plurality of electrode pads 11a may include at least one ground pad.

Each of the plurality of electrode pads 11a and at least one electrode pad 11b is connected to one corresponding first lead 3A or 3B of the plurality of first leads 3A and the plurality of first leads 3B via the at least one of the plurality of wires 7. In the example shown in FIG. 6, each of the four electrode pads 11a is connected to one corresponding first lead 3A of the four first leads 3A via one wire 7. Each of the two electrode pads 11b is connected to one first lead 3B closest to the electrode pad 11b of the two first leads 3B via one wire 7.

In the manufacturing method of the electronic component 10, next, an encapsulating process is performed in which the die pads 2, the first leads 3A and 3B, and the chip 11 are encapsulated by the encapsulating resin 9. In the encapsulating process, the first connection bars 61A and 61B and the second connection bars 62A and 62B of the frame members 6 of the lead frames 1 are also encapsulated. Hereafter, a structure produced in the encapsulating process, which includes the lead frames 1 and the encapsulating resin 9, is referred to as a basic structure.

Each of the first leads 3A and 3B includes a first portion and a second portion arranged between the first portion and the die pad 2. In the basic structure, the first portion of each of the first leads 3A and 3B is connected to the first connection bar 61A or 61B. The first portion may be exposed at the portion of the encapsulating resin 9 to be the bottom surface 12A of the body 12. The second portion may be entirely covered with the encapsulating resin 9. Similarly, each of the plurality of connecting leads 4B may be entirely covered with the encapsulating resin 9. In the basic structure, the die pad 2 may be exposed at the portion of the encapsulating resin 9 to be the bottom surface 12A of the body 12.

The lead frame 1 may have such a shape that the second portions of the respective first leads 3A and 3B and the plurality of connecting leads 4B are covered with the encapsulating resin 9 as described above. Specifically, the lead frame 1 may have such a structure that the second portions of the respective first leads 3A and 3B and the plurality of connecting leads 4B are shifted in the Z direction with respect to the die pad 2 and the first portions of the respective first leads 3A and 3B.

Alternatively, the thicknesses of the second portions of the respective first leads 3A and 3B and the plurality of connecting leads 4B (dimension in a direction parallel to the Z direction) may be smaller than the thicknesses of the die pad 2 and the first portions of the respective first leads 3A and 3B. In this case, the second portions of the respective first leads 3A and 3B and the two connecting leads may be processed before the encapsulating process so that the thicknesses of the second portions of the respective first leads 3A and 3B and the plurality of connecting leads 4B would be small. For example, etching from the −Z direction side of the lead frame 1 may be performed to reduce the thicknesses of the second portions of the respective first leads 3A and 3B and the plurality of connecting leads 4B.

In the manufacturing method of the electronic component 10, the basic structure is then secured to a not-shown dicing tape. Next, a cutting process is performed in which the basic structure is cut by a dicing saw such that the first connection bars 61A and 61B are removed. By the cutting process, cut surfaces of the first leads 3A and 3B are exposed from the encapsulating resin 9. In the cutting process, the basic structure may be cut such that the basic structure is not divided, in other words, such that the third connection bar 101 and the fourth connection bar are not completely cut off. Each of the plurality of first leads 3A is connected to the second connection bar 62A or 62B via a corresponding one of the plurality of second leads 4A. The plurality of first leads 3B are connected to the second connection bars 62A and 62B via the die pad 2 and the two connecting leads. The second connection bars 62A and 62B are connected to the fifth connection bar 102 and the sixth connection bar.

In the manufacturing method of the electronic component 10, the plating layers are then formed on exposed surfaces of the first leads 3A and 3B not covered with the encapsulating resin 9, and a plating layer is formed on an exposed surface of the die pad 2 not covered with the encapsulating resin 9, by electroplating, for example. When the electroplating is used, the plating layer can be formed by connecting an electrode of an electroplating device to at least one of the third connection bar 101, the not-shown fourth connection bar, the fifth connection bar 102, and the not-shown sixth connection bar.

In the manufacturing method of the electronic component 10, the plurality of electronic components 10 are then divided from one another by cutting the basic structure such that the second connection bars 62A and 62B are removed. Thereby, the electronic component 10 is completed. Note that, in the electronic component 10, the plurality of first leads 3B are in a state of not being connected, either directly or indirectly, to the plurality of second leads 4A.

Here, with reference to FIGS. 1 to 3, a relationship between the plurality of first terminals 13A and the plurality of first leads 3A and a relationship between the plurality of second terminals 13B and the plurality of first leads 3B will be described. FIG. 3 shows one first terminal 13A and one second terminal 13B. The first terminal 13A is constituted of the first lead 3A and the plating layer 30. For convenience, a surface of the first lead 3A not covered with the encapsulating resin 9 is referred to as an exposed surface. The plating layer 30 covers the exposed surface of the first lead 3A. The second terminal 13B is constituted of the first lead 3B and the plating layer 30. For convenience, a surface of the first lead 3B not covered with the encapsulating resin 9 is referred to as an exposed surface. The plating layer 30 covers the exposed surface of the first lead 3B.

The description of the one first terminal 13A above is also applicable to the other three first terminals 13A. Similarly, the description of the one second terminal 13B above is also applicable to the one other second terminal 13B.

The first terminal 13A shown in FIGS. 1 and 2 is a part constituted of the first portion of the first lead 3A. The portion of the first terminal 13A covered with the encapsulating resin 9 (portion not shown in FIGS. 1 and 2) is constituted of the second portion of the first lead 3A.

Similarly, the second terminal 13B shown in FIGS. 1 and 2 is a part constituted of the first portion of the first lead 3B. The portion of the second terminal 13B covered with the encapsulating resin 9 (portion not shown in FIGS. 1 and 2) is constituted of the second portion of the first lead 3B.

Next, the operations and effects of the lead frame 1 and electronic component 10 according to the example embodiment will be described. In the example embodiment, the number of the second leads 4A is smaller than the total number of the plurality of first leads 3A and the plurality of first leads 3B. Here, consider a lead frame of a comparison example that all the plurality of first leads 3A and 3B are connected to the second connection bar 62A or 62B via a plurality of second leads of the comparison example. In a case of manufacturing the electronic component 10 by using the lead frame of the comparison example, cut surfaces of the plurality of second leads of the comparison example and cut surfaces of the plurality of connecting lead 4B are exposed at the side surfaces 12E and 12F of the body 12 of the electronic component 10.

In the electronic component 10 manufactured using the lead frame of the comparison example, the number of the second leads of the comparison example exposed at the side surfaces 12E and 12F of the body 12 is equal to the total number of the plurality of first leads 3A and the plurality of first leads 3B.

In contrast to this, in the example embodiment, the number of the second leads 4A exposed at the side surfaces 12E and 12F of the body 12 is equal to the number of the plurality of first leads 3A and is hence smaller than the total number of the plurality of first leads 3A and the plurality of first leads 3B. Thus, according to the example embodiment, the risk of moisture intrusion into the body 12 can be reduced.

In the example embodiment, each of the plurality of first leads 3B is connected to the die pad 2. The die pad 2 is connected to the second connection bars 62A and 62B via the plurality of connecting leads 4B. Thus, according to the example embodiment, each of the plurality of first leads 3B can be electrically connected to the second connection bars 62A and 62B via the die pad 2 and the plurality of connecting leads 4B. Thus, according to the example embodiment, the plating layer 30 can be formed for each of the plurality of first leads 3B.

Furthermore, according to the example embodiment, by reducing the number of the plurality of second leads 4A, abrasion of the dicing saw can be suppressed.

### MODIFICATION EXAMPLE

Next, a modification example of the lead frame 1 and the electronic component 10 according to the example embodiment will be described. In the modification example, the number of first leads 3A and the number of second leads 4A of the lead frame 1 are different from those of the example shown in FIG. 5. In the modification example, the number of the first leads 3A is eight, and the number of the second leads 4A is eight. In the modification example, the number of the electrode pads 11b of the chip 11 is different from that of the example shown in FIG. 6. In the modification example, the number of the electrode pads 11a is eight.

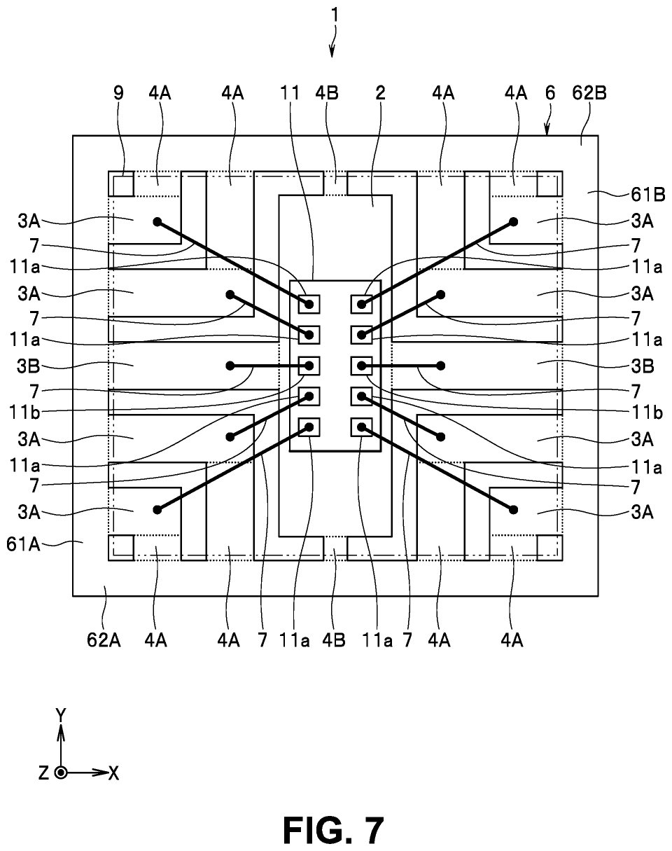

FIG. 7 is a plan view showing a connection relationship between the first leads 3A and 3B and the electrode pads 11a and 11b. Here, one first lead 3B arranged between the die pad 2 and the first connection bar 61A (on the left side of the die pad 2 in FIG. 7) is referred to as a left first lead 3B for convenience, while the one other first lead 3B arranged between the die pad 2 and the first connection bar 61B (on the right side of the die pad 2 in FIG. 7) is referred to as a right first lead 3B for convenience. In the modification example, each two first leads 3A are arranged between the left first lead 3B and the second connection bar 62A, between the left first lead 3B and the second connection bar 62B, between the right first lead 3B and the second connection bar 62A, and between the right first lead 3B and the second connection bar 62B.

Four first leads 3A arranged between the die pad 2 and the first connection bar 61A are aligned along the first connection bar 61A. Each of the four first leads 3A is connected to the first connection bar 61A and extends in the X direction from the first connection bar 61A. Each of the four second leads 4A of the plurality of second leads 4A is connected near an end portion of one corresponding first lead 3A of the four first leads 3A, the end portion being opposite to the first connection bar 61A.

The four other first leads 3A arranged between the die pad 2 and the first connection bar 61B are aligned along the first connection bar 61B. Each of the four other first leads 3A is connected to the first connection bar 61B and extends in the −X direction from the first connection bar 61B. Each of the four other second leads 4A of the plurality of second leads 4A is connected near an end portion of one corresponding first lead 3A of the four other first leads 3A, the end portion being opposite to the first connection bar 61B.

In FIG. 7, the boundary between each of the first leads 3A and 3B and the first connection bar 61A or 61B, the boundary between each of the first leads 3A and each of the second leads 4A, and the boundary between each of the first leads 3B and the die pad 2 are indicated by dotted lines.

Here, one connecting lead 4B arranged between the die pad 2 and the second connection bar 62A (on the lower side of the die pad 2 in FIG. 7) is referred to as a lower connecting lead 4B for convenience, while the one other connecting lead 4B arranged between the die pad 2 and the second connection bar 62B (on the upper side of the die pad 2 in FIG. 7) is referred to as an upper connecting lead 4B for convenience. In the modification example, each two second leads 4A are arranged between the lower connecting lead 4B and the first connection bar 61A, between the lower connecting lead 4B and the first connection bar 61B, between the upper connecting lead 4B and the first connection bar 61A, and between the upper connecting lead 4B and the first connection bar 61B. Four second leads 4A arranged between the die pad 2 and the second connection bar 62A are aligned along the second connection bar 62A and also connected to the second connection bar 62A. The four other second leads 4A arranged between the die pad 2 and the second connection bar 62B are aligned along the second connection bar 62B and also connected to the second connection bar 62B. In FIG. 7, the boundary between the die pad 2 and each of the connecting leads 4B, the boundary between each of the second leads 4A and the second connection bar 62A or 62B, and the boundary between the each of the connecting leads 4B and the second connection bar 62A or 62B are indicated by dotted lines.

As described above, in the manufacturing process of the electronic component 10, the electrode pads 11a and 11b of the chip 11 and the first leads 3A and 3B of the lead frame 1 are connected by wire bonding using the plurality of wires 7. In particular, in the modification example, each of the eight electrode pads 11a is connected to one corresponding first lead 3A of the eight first leads 3A via one wire 7.

### Second Example Embodiment

Next, a second example embodiment of the technology will be described. A lead frame 201 according to the example embodiment is different from the lead frame 1 according to the first example embodiment in the following respects. The lead frame 201 according to the example embodiment includes a plurality of first leads 3C, instead of the plurality of first leads 3B of the first example embodiment. The plurality of first leads 3C correspond to the “at least one particular first lead” in the technology. In particular, in the example embodiment, the number of the plurality of first leads 3C is two. The other configuration of the lead frame 201 according to the example embodiment is the same as the configuration of the lead frame 1 according to the first example embodiment.

In the example embodiment, the electronic component 10 is manufactured using the lead frame 201 according to the example embodiment. As in the first example embodiment, in a manufacturing process of the electronic component 10, the electrode pads 11a and 11b of the chip 11 and the first leads 3A and 3C of the lead frame 1 are connected by wire bonding using the plurality of wires 7. In particular, in the example embodiment, two electrode pads 11b are connected to two first leads 3C via two wires 7.

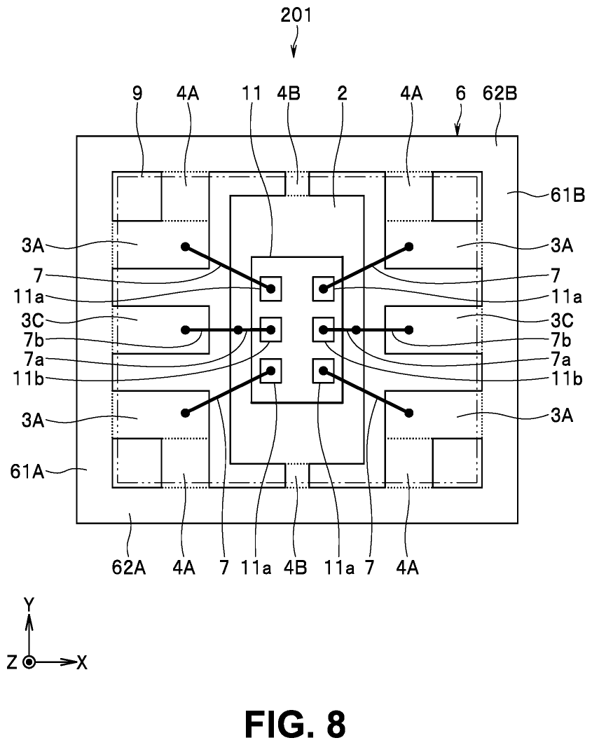

In the following, with reference to FIG. 8, the shape and arrangement of the two first leads 3C and a connection relationship between the two first leads 3C and the plurality of electrode pads 11b will be described in detail. FIG. 8 is a plan view showing a connection relationship between the first leads 3A and 3C and the electrode pads 11a and 11b.

One of the first leads 3C is arranged between two first leads 3A between the die pad 2 and the first connection bar 61A. The one first lead 3C is connected to the first connection bar 61A and extends in the X direction from the first connection bar 61A. The one other first lead 3C is arranged between two other first leads 3A between the die pad 2 and the first connection bar 61B. The one other first lead 3C is connected to the first connection bar 61B and extends in the −X direction from the first connection bar 61B. In FIG. 8, the boundary between each of the two first leads 3C and the first connection bar 61A or 61B is indicated by a dotted line. Neither of the two first leads 3C is connected to the die pad 2 and the plurality of second leads 4A.

As described above, two electrode pads 11b are connected to two first leads 3C via the two wires 7. Here, of the two wires 7, the wire 7 connected to the electrode pad 11b is referred to as a first wire 7a, while the wire 7 connected to the first lead 3C is referred to as a second wire 7b. Each of the two electrode pads 11b is connected to the die pad 2 via the first wire 7a. Each of the two first leads 3C is connected to the die pad 2 via the second wire 7b. Hence, in other words, the two electrode pads 11b are connected to the two first leads 3C via the first and second wires 7a and 7b.

The configuration, operation, and effects of the example embodiment are otherwise the same as those of the first example embodiment.

Note that the technology is not limited to the foregoing example embodiments, and various modifications may be made thereto. For example, the shapes, numbers, and arrangement of the leads are not limited to the examples described in the example embodiments and may be optional as long as the requirements set forth in the claims are satisfied. The number of the first leads 3A and the number of the second leads 4A may each be any number equal to or larger than two, other than four or eight. The number of the first leads 3B or 3C may be one, or three or more.

The shape of each of the leads is not limited to a rectangle and may be polygonal, circular or elliptical.

The number and arrangement of the electrode pads of the chip 11 are not limited to the examples described in the example embodiments and may be optional as long as the requirements set forth in the claims are satisfied. In particular, the number of the electrode pads may be smaller than the total number of the first leads 3A and the first leads 3B or 3C.

Some of the plurality of first leads 3A may be connected to the second connection bar 62A or 62B by wires instead of the second leads 4A.

As described above, a lead frame according to one embodiment of the technology is a lead frame for an electronic component. The lead frame includes a die pad, a plurality of leads, and a frame member surrounding the die pad and the plurality of leads. The frame member includes a first connection bar extending in a first direction and a second connection bar extending in a second direction. The die pad is connected to a second connection bar. The plurality of leads include a plurality of first leads connected to the first connection bar and a plurality of second leads connected to the second connection bar. The number of the plurality of second leads is smaller than the number of the plurality of first leads. Each of the plurality of second leads is connected to one corresponding first lead of the plurality of first leads.

In the lead frame according to one embodiment of the technology, the plurality of first leads may include at least one particular first lead. The at least one particular first lead may be connected to the die pad and need not necessarily be connected to the plurality of second leads. Alternatively, the at least one particular first lead need not necessarily be connected to the die pad and the plurality of second leads.

An electronic component according to one embodiment of the technology is an electronic component manufactured using the lead frame according to one embodiment of the technology. The electronic component includes a chip mounted on the die pad and an encapsulating resin encapsulating the chip.

In the electronic component according to one embodiment of the technology, the plurality of first leads may include at least one particular first lead. The at least one particular first lead may be connected to the die pad and need not necessarily be connected to the plurality of second leads. The at least one particular first lead may include a first portion and a second portion arranged between the first portion and the die pad. The second portion may be entirely covered with an encapsulating resin.

Alternatively, the at least one particular first lead need not necessarily be connected to the die pad and the plurality of second leads. The electronic component according to one embodiment of the technology may further include at least one wire electrically connecting the at least one particular first lead and the die pad.

The electronic component according to one embodiment of the technology may further include a plurality of wires. The chip may include a plurality of electrode pads. Each of the plurality of electrode pads may be electrically connected to one corresponding first lead of the plurality of first leads via at least one of the plurality of wires. The plurality of first leads may include at least one particular first lead. The plurality of electrode pads may include at least one particular electrode pad. The plurality of wires may include a first wire and a second wire. The at least one particular electrode pad may be electrically connected to the die pad via the first wire. The at least one particular first lead may be electrically connected to the die pad via the second wire. The at least one particular first lead may be electrically connected to the ground.

In the electronic component according to one embodiment of the technology, each of the plurality of first leads may include an exposed surface not covered with an encapsulating resin. The electronic component according to one embodiment of the technology may further include a plating layer covering the exposed surface.

Obviously, many modifications and variations of the technology are possible in the light of the above teachings. Thus, it is to be understood that, within the scope of the appended claims and equivalents thereof, the technology may be practiced in other embodiments than the foregoing example embodiments.

What is claimed is:

1. A lead frame for an electronic component, the lead frame comprising:
a die pad;
a plurality of leads; and
a frame member surrounding the die pad and the plurality of leads, wherein
the frame member includes a first connection bar extending in a first direction and a second connection bar extending in a second direction,
the die pad is connected to the second connection bar,
the plurality of leads include a plurality of first leads connected to the first connection bar and a plurality of second leads connected to the second connection bar,
the number of the plurality of second leads is smaller than the number of the plurality of first leads, and
each of the plurality of second leads is connected to one corresponding first lead of the plurality of first leads.

2. The lead frame according to claim 1, wherein
the plurality of first leads include at least one particular first lead, and
the at least one particular first lead is connected to the die pad and is not connected to the plurality of second leads.

3. The lead frame according to claim 1, wherein
the plurality of first leads include at least one particular first lead, and
the at least one particular first lead is connected to neither the die pad nor the plurality of second leads.

4. An electronic component manufactured using the lead frame according to claim 1, the electronic component comprising:
a chip mounted on the die pad; and
an encapsulating resin encapsulating the chip.

5. The electronic component according to claim 4, wherein
the plurality of first leads include at least one particular first lead, and
the at least one particular first lead is connected to the die pad and is not connected to the plurality of second leads.

6. The electronic component according to claim 5, wherein
the at least one particular first lead includes a first portion and a second portion arranged between the first portion and the die pad, and
the second portion is entirely covered with the encapsulating resin.

7. The electronic component according to claim 4, wherein
the plurality of first leads include at least one particular first lead, and
the at least one particular first lead is connected to neither the die pad nor the plurality of second leads,
the electronic component further comprising
at least one wire electrically connecting the at least one particular first lead and the die pad.

8. The electronic component according to claim 4, further comprising
a plurality of wires, wherein
the chip includes a plurality of electrode pads, and
each of the plurality of electrode pads is electrically connected to one corresponding first lead of the plurality of first leads via the at least one of the plurality of wires.

9. The electronic component according to claim 8, wherein
the plurality of first leads include at least one particular first lead,
the plurality of electrode pads include at least one particular electrode pad,
the plurality of wires include a first wire and a second wire,
the at least one particular electrode pad is electrically connected to the die pad via the first wire, and
the at least one particular first lead is electrically connected to the die pad via the second wire.

10. The electronic component according to claim 9, wherein the at least one particular first lead is electrically connected to ground.

11. The electronic component according to claim 4, wherein
each of the plurality of first leads includes an exposed surface not covered with the encapsulating resin,
the electronic component further comprising
a plating layer covering the exposed surface.
